(19) United States
(12) Patent Application Publication
(10) Pub. No.: US 2008/0073797 A1
(43) Pub. Date: Mar. 27, 2008

(54) Semiconductor die module and package and fabricating method of semiconductor package

(75) Inventors: Sang-Hyun Kim, Yongin-si (KR); Shi-Yun Cho, Dongan-Anyang-si (KR); Ho-Seong Seo, Suwon-si (KR); Youn-Ho Choi, Suwon-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/899,902

(22) Filed: Sep. 6, 2007

(30) Foreign Application Priority Data
Sep. 25, 2006 (KR) 2006-92829

(51) Int. Cl. H01L 23/52; H01L 21/00

(52) U.S. Cl. 257/777; 438/109; 257/E21.001; 257/E23.141

(57) ABSTRACT

A semiconductor die module, a semiconductor package, and a fabrication method of the semiconductor package. A method for manufacturing a semiconductor package includes the steps of: preparing a printed circuit board in which a hole is formed to extend through a core, and an insulation layer and a circuit pattern are formed on a surface of the core, the printed circuit board having an open surface; forming conductive bumpers on some of the electric pads of each semiconductor die; forming a semiconductor die module in which the electric pads of each semiconductor die are connected to one another; inserting the semiconductor die module into the hole of the core so as to safely seat the semiconductor die module on the insulation layer and the circuit pattern; and forming the insulation layer and the circuit patterns on an open upper surface of the core.

### CLAIM OF PRIORITY

This application claims priority an application entitled “Semiconductor Die Module and Package and Fabricating Method of Semiconductor Package” filed in the Korean Intellectual Property Office on Sep. 25, 2006 and assigned Serial No. 2006-92829, the contents of which are hereby incorporated by reference.

### BACKGROUND OF THE INVENTION

1. Field of the Invention

The present invention relates to a semiconductor package, and more particularly to a semiconductor package in which a semiconductor die is mounted on a printed circuit board, and a fabricating method thereof.

2. Description of the Related Art

A System In Package (SIP) refers to a package for modulating large scale integrated circuits such as a semiconductor die, which is applied to portable terminals which have difficulty in securing a mounting space. Recently, the SIP has been applied to various fields.

The SIP may be classified into a wire bonding-type SIP, a package on package-type SIP, a via-type SIP, and an embedded-type SIP. In the wire bonding-type SIP, semiconductor dies are laminated and connected to one another by wire-bonding. In the package on package-type SIP, thin packages are laminated. In the via-type SIP, a via hole is penetrated through a silicone chip. In the embedded-type SIP, a chip size package of a wafer level is embedded in a resin substrate.

Instead of the SIP that includes a semiconductor die mounted directly on the printed circuit board, such as a surface mounted device of a semiconductor die, and that includes separate integration, the SIP capable of integrating the semiconductor die on a printed circuit board in small volume and large scale integration has been proposed.

FIGS. 1 and 2 are views showing conventional semiconductor packages in which semiconductor dies are mounted directly on the printed circuit boards. Referring to FIGS. 1 and 2, the semiconductor packages 100 and 200 have semiconductor dies 121, 122, 221 and 222 mounted on the printed circuit boards 110 and 210. The semiconductor dies 121, 122, 221 and 222 are electrically connected to one another through the printed circuit boards 110 and 210.

An embedded-type printed circuit board may be used as the printed circuit board 110 and 210, in which circuit patterns 113 and 213 are formed on the upper and lower portions of the cores 111 and 211.

In the printed circuit boards 110 and 210, insulation layers 112 and 212 and conductive layers may be alternately and repeatedly laminated on both surfaces of each core 111 or 211. The circuit patterns 113 and 213 having desired shape may be formed on each layer by etching. The circuit patterns 113 and 213 formed on both surfaces of the cores 111 and 211 may be electrically connected to one another by conductive epoxy resin filled in via holes penetrating through the cores 111 and 211.

The circuit patterns 113 and 213 enable the mounted semiconductor dies 121, 122, 221 and 222 to be electrically connected with one another, or play the role as exterior input and output terminals.

FIG. 1 is a view showing a semiconductor package 100 in which semiconductor dies 121 and 122 are mounted on an identical printed circuit board 110, and FIG. 2 is a view showing a semiconductor package 200 in which semiconductor dies 221 and 222 are mounted on a laminate printed circuit board 210. In the semiconductor packages 100 and 200 as shown in FIGS. 1 and 2, semiconductor dies 121, 122, 221 and 222 are electrically connected to one another through corresponding circuit patterns 113 and 213.

However, the semiconductor packages shown in FIGS. 1 and 2 have several disadvantages. In particular, the semiconductor package shown in FIG. 1 must have a large surface area. In addition, the semiconductor dies must be routed on the printed circuit board.

Meanwhile, the semiconductor package shown in FIG. 2 requires a separate routing in order to achieve internal connection among the semiconductor dies. The length required for separate routing is extensive.

### SUMMARY OF THE INVENTION

Accordingly, the present invention has been made to solve the deficiencies of the prior art and provide additional advantages by providing a semiconductor package in which a plurality of semiconductor dies is mounted on a printed circuit board even if wiring and volume are reduced.

According to an aspect of the present invention, a semiconductor die module includes at least two semiconductor dies, wherein each of the semiconductor dies includes electric pads for internal wiring on one surface of the semiconductor die and conductive bumpers arranged around the electric pads, and the electric pads are connected to one another.

According to another aspect of the present a semiconductor package includes: a semiconductor module including at least two semiconductor dies, each of which has electric pads for internal wiring on a surface of the semiconductor die and conductive bumpers arranged around the electric pads, the electric pads being connected to one another; and a laminate-type printed circuit board on which the semiconductor die module is mounted and a circuit pattern is formed and connected to each semiconductor die.

According to another aspect of the present invention, a method for fabricating a semiconductor package is provided. The method includes the steps of: preparing a printed circuit board in which a hole is formed to extend through a core and an insulation layer and a circuit pattern are formed on a surface of the core, the printed circuit board having an open surface; forming conductive bumpers on some of electric pads of each semiconductor die; forming a semiconductor die module in which the electric pads of each semiconductor die are connected to one another; inserting the semiconductor die module into the hole of the core so as to safely seat the semiconductor die module on the insulation layer and the circuit pattern; and forming the insulation layer and the circuit patterns on an open upper surface of the core.

### BRIEF DESCRIPTION OF THE DRAWINGS

The above and other objects, features, and advantages of the present invention will be more apparent from the following detailed description taken in conjunction with the accompanying drawings, in which:

FIGS. 1 and 2 are sectional views showing a conventional semiconductor package;

FIGS. 3A to 3C are sectional views showing a semiconductor package according to one aspect of the present invention and the steps of manufacturing the semiconductor package;

FIG. 4 is a perspective view showing semiconductor dies constructing a semiconductor die module shown in FIG. 3; and

FIG. 5 is a view showing an electric pad and conductive bumpers constructing the semiconductor die module shown in FIG. 4.

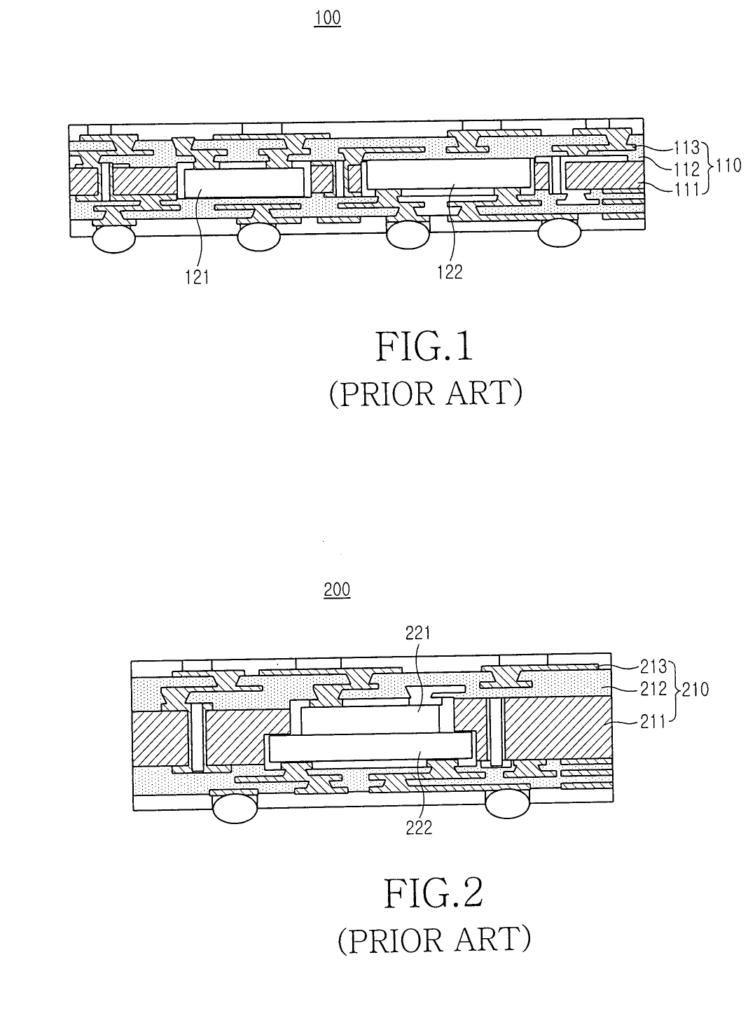

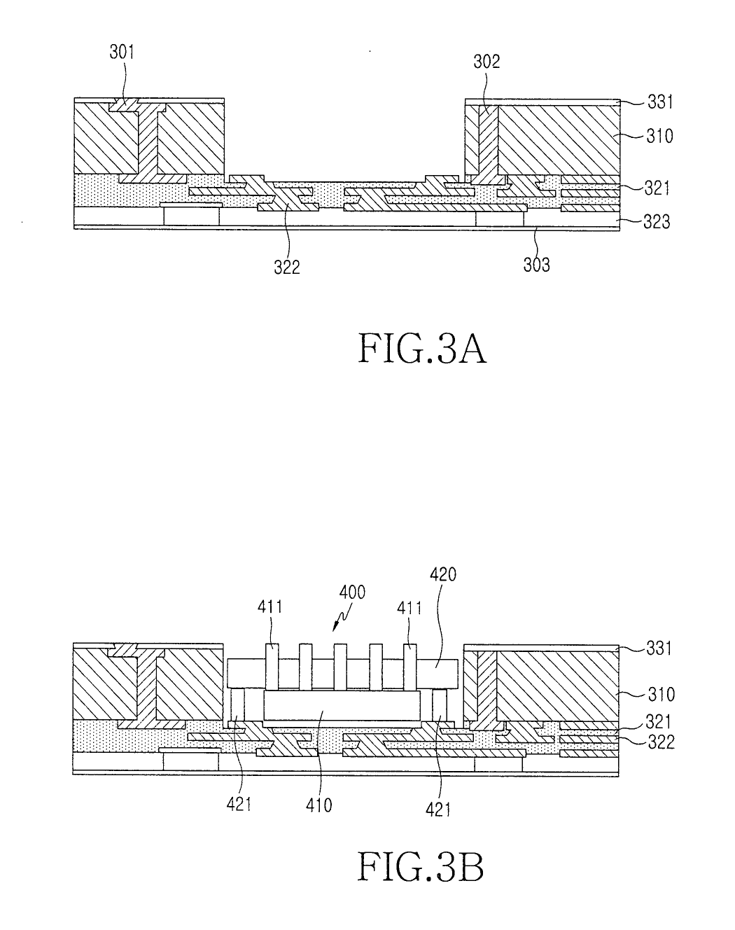

### DETAILED DESCRIPTION OF THE PRESENT INVENTION

Hereinafter, several aspects of the present invention will be described in detail with reference to the accompanying drawings. In the following description of the present invention, a detailed description of known functions and configurations is omitted as it may make the subject matter of the present invention unclear.

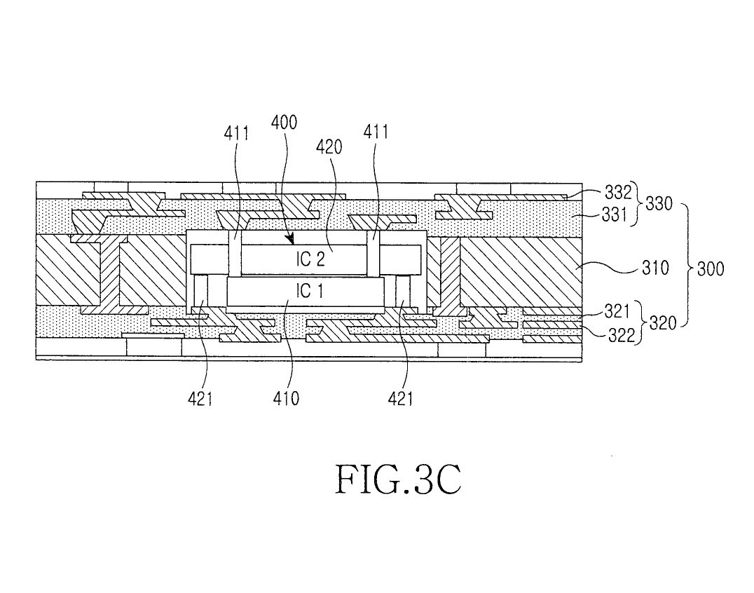

FIGS. 3A to 3C are sectional views showing a semiconductor package according to one aspect of the present invention, in which the semiconductor package is manufactured according to steps illustrated in the figures. Referring to FIGS. 3A to 3C, the semiconductor and the method for manufacturing the same according to the present invention will be described.

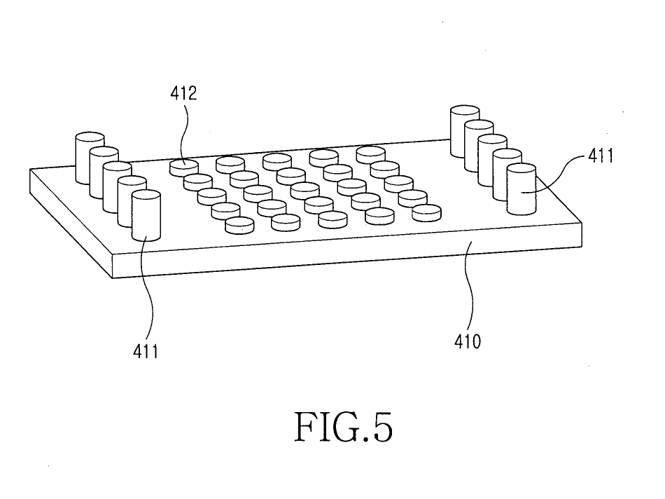

The semiconductor package according to one aspect of the present invention includes a semiconductor die module 400. The semiconductor die module 400 includes semiconductor dies 410 and 420 that have conductive bumpers 411 and 421 and that are connected to each other by the electric pads 412 (an example of which is shown in FIG. 5). In addition, the semiconductor die module 400 includes a printed circuit board 300 with circuit patterns 322 and 332 that are connected to the conductive bumpers 421, the printed circuit board 300 on which the semiconductor die module 400 is mounted.

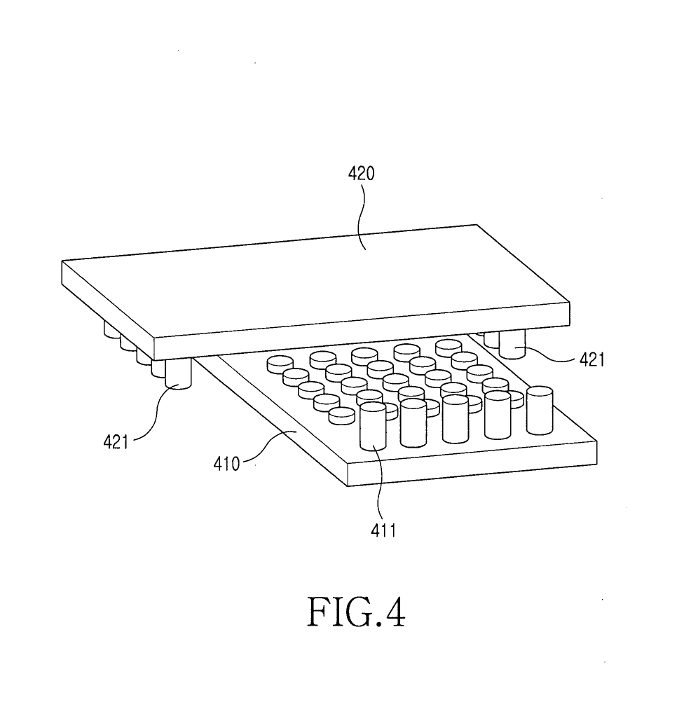

FIG. 4 is a perspective view showing the semiconductor dies 410 and 420 of the semiconductor die module 400 shown in FIG. 3. FIG. 5 is a view showing the electric pad 412 and the conductive bumpers 411 of the semiconductor die 410 shown in FIG. 4. Referring to FIGS. 4 and 5, the semiconductor die module 400 and the semiconductor dies 410 and 420 will be described.

As illustrated in FIGS. 4 and 5, the semiconductor dies 410 and 420 includes the electric pads 412 arranged on a surface thereof, and the conductive bumpers 411 and 421 arranged around the electric pads 412, as the semiconductor die 420 also includes electric pads corresponding to electric pad 412 of the semiconductor 410.

The semiconductor dies 410 and 420 are connected to each other in such a manner that surfaces having the conductive bumpers 411 and 421 and the electric pads 412 face each other. In addition, the semiconductor dies 410 and 420 are coupled to each other in such a manner that electric pads 412 of the semiconductor dies are coupled to each other in a pad to pad configuration.

The conductive bumpers 411 and 421, which are arranged around the electric pads 412, are electrically connected to the corresponding circuit patterns on the printed circuit board 300 as an outer electric source or signal input/output ports. In particular, the conductive bumpers 411 and 421 have lengths longer than the thickness of the semiconductor dies 410 and 420, and the bumpers 411 and 421 are electrically connected to the circuit patterns 322 and 332 when seated on the printed circuit board 300.

The printed circuit board 300 includes a core 310; insulation layers 321 and 331, formed on upper and lower surfaces of the core 310; and lower and upper layers 320 and 330, on which the circuit patterns 322 and 332, the circuit patterns 322 and 332 formed on the insulation layers 321 and 331, are formed.

The core 310, having holes extending from the upper surface to the lower surface, is made of a material having an insulation characteristic. The semiconductor module 400 is mounted in some of the holes, where a conductive filling material is filled in some of the remaining holes, so as to electrically connect the circuit patterns 322 and 332, on the upper and lower layers 320 and 310, to each other.

The insulation layers 321 and 331, and the conductive metal sheet, etc. are repeatedly laminated and etched to form the circuit patterns 322 and 332. Some of the circuit patterns 322 and 332 formed on the upper and lower surfaces of the core 310 may be electrically connected to one another by the conductive connection members 301 and 302. The conductive connection members 301 and 302 are filled as a conductive filling material in the holes of the core 310.

The insulation layer 331 and the circuit pattern 332 of the upper layer 330 are formed on the upper surface of the core 310 after the semiconductor die module 400 is mounted within the core 310.

The semiconductor package according to the present invention is manufactured by forming holes through the core 310 and forming an insulation layer 321 and a circuit pattern 332 on a lower surface of the core 310, so as to manufacture a printed circuit board 300; forming conductive bumpers 411 and 421 protruding from some of electric pads in at least two semiconductor dies 410 and 420; forming a semiconductor die module 400, in which the electric pads of each semiconductor dies 410 and 420 are connected to each other; inserting the semiconductor die module 400 in the holes of the core 310 so as to seat the semiconductor die module 400 on the insulation layer 321 and the circuit pattern 322; and forming an insulation layer 331 and circuit patterns 332 on an upper open surface of the core 310.

Some of circuit patterns 332 on the upper layer 330 are connected to the corresponding conductive bumpers 411 of the semiconductor dies 410 and 420. The semiconductor die module 400 is seated so that the conductive bumpers 421 of the corresponding semiconductor die 420 is connected to the corresponding circuit pattern 322 formed on the lower layer 320.

The electric pads 412 of each semiconductor die 410 or 420 are connected to the electric pads of the corresponding semiconductor die 410 or 420 bumper to bumper. The conductive bumper may be formed on and connected to the electric pad by a reflow. In one non-limiting example, the conductive bumpers can be formed on some (a portion) of the electric pads such that the conductive bumpers are arranged around a remainder (remain portion) of the plurality of electric pads. It is within the spirit and scope of the invention and the appended claims that the arrangement of the conductive bumpers may not completely surround the remaining electric pads, for example, they may be arranged, for example at two opposing ends, or in other configurations.

According to the present invention, a laminate-type semiconductor die module, on which semiconductor dies are laminated, is mounted on the core of a printed circuit board In addition, a conductive bumper is formed on each semiconductor die so that the circuit pattern of the printed circuit board can be connected directly to the semiconductor dies. Thus, it is possible to secure additional space.

In addition, as the semiconductor dies are directly connected to a printed circuit board, one advantage of the present invention is that forming a separate routing to connect the semiconductor dies to the printed circuit board is no longer necessary. In other words, it is possible to reduce space, time, and manufacturing costs of the semiconductor package.

While the invention has been shown and described with reference to particular aspects, it will be understood by those skilled in the art that various changes in form and details may be made therein without departing from the spirit and scope of the invention as defined by the appended claims.

What is claimed is:

1. A semiconductor die module comprising:
at least two semiconductor dies,
wherein each of the semiconductor dies includes a plurality of electric pads on one surface of the semiconductor die and conductive bumpers arranged around the electric pads, and
wherein the electric pads of one semiconductor die are connected to the electric pads of another semiconductor die.

2. The semiconductor die module as claimed in claim 1, wherein length of the conductive bumpers has a value greater than the value of thickness of a corresponding semiconductor die.

3. A semiconductor package comprising:
a semiconductor module including at least two semiconductor dies, each semiconductor dies having electric pads on a surface of the semiconductor die and conductive bumpers arranged around the electric pads, the electric pads of one semiconductor die being coupled to the electric pads of another semiconductor die; and
a laminate-type printed circuit board including the semiconductor die module mounted thereon and a circuit pattern that is formed and connected to each semiconductor die.

4. The semiconductor package as claimed in claim 3, wherein the printed circuit board comprises:
a core having a groove that is configured to receive the semiconductor die module;
insulation layers disposed on upper and lower surfaces of the core;
conductive circuit patterns formed on the insulation layers; and
conductive connection members being configured to extending through the core and to connect circuit patterns disposed on upper and lower portions of the core.

5. The semiconductor package as claimed in claim 3, wherein the conductive bumper of each semiconductor die is connected to the corresponding circuit pattern.

6. The semiconductor package as claimed in claim 4, wherein the core has insulation characteristics.

7. A method for fabricating a semiconductor package, comprising the steps of:
preparing a printed circuit board including a hole, a circuit pattern, and an open surface, the hole extending through a core and an insulation layer, and the circuit pattern being formed on a surface of the core;
preparing at least two semiconductor dies, each including a plurality of electric pads;
forming conductive bumpers on some electric pads of said plurality of electric pads of each semiconductor die so that the conductive bumpers are arranged around a remainder of the plurality of electric pads;
forming a semiconductor die module in which the electric pads of one semiconductor die are connected to the electric pads of another semiconductor die;
inserting the semiconductor die module into the hole of the core and seating the semiconductor die module on the insulation layer and the circuit pattern; and
forming the insulation layer and the circuit patterns on an open upper surface of the core.

8. The method as claimed in claim 7, wherein the semiconductor die module is seated on the printed circuit board so that the conductive bumpers of each semiconductor die are directly connected to the corresponding printed circuit board.

9. The method as claimed in claim 7, wherein the electric pads of each semiconductor die are connected to one another in a pad-to-pad configuration.

10. The method as claimed in claim 7, further comprising
forming the circuit pattern by laminating the insulation layer and a conductive metal sheet and by etching the laminated insulation layer and conductive metal sheet.
